(19) United States
(12) Patent Application Publication
(10) Pub. No.: US 2026/0211030 A1
(43) Pub. Date: Jul. 23, 2026

(54) OPTICAL PROBE SYSTEM AND CALIBRATION CHUCK THEREOF, DISTANCE MEASURING METHOD, METHOD OF PERFORMING OPTICAL TESTING AND ELECTRONIC DEVICE UNDER TEST

(71) Applicant: MPI CORPORATION, Zhubei City (TW)

(72) Inventors: STOJAN KANEV, Zhubei City (TW); PO-YI TING, Zhubei City (TW); TING-AN YEN, Zhubei City (TW); YU-HSUN HSU, Zhubei City (TW); SEBASTIAN GIESSMANN, Zhubei City (TW)

(21) Appl. No.: 19/410,008

(22) Filed: Dec. 5, 2025

Related U.S. Application Data
(60) Provisional application No. 63/772,801, filed on Mar. 17, 2025.
(60) Provisional application No. 63/746,281, filed on Jan. 17, 2025.

(51) Int. Cl. G01R 31/28; G01M 11/02

(52) U.S. Cl. CPC G01R 31/2891; G01M 11/0207; G01R 31/2875; G01R 31/2877

(57) ABSTRACT

An optical probe system and a calibration chuck thereof, a distance measuring method for at least one optical probe, a method of performing an optical testing on an electronic device under test, and an electronic device under test configured to be tested by the above-mentioned method. The calibration chuck for the optical probe system can be equipped with a thermal control module to ensure that a simulated test temperature environment applied to the calibration chuck and an actual test temperature environment applied to the optical probe system can be provided to at least one optical probe at the same or similar temperatures, so that a calibrated fiber-to-sensor distance measured at a simulated test temperature applied to the calibration chuck can remain consistent with a measured fiber-to-sensor distance measured at an actual test temperature applied to a thermal main chuck of the optical probe system.

### CROSS-REFERENCE TO RELATED PATENT APPLICATION

This application claims the benefit of priority to the U.S. Provisional Patent Application Ser. No. 63/746,281 filed on January 17, 2025, and Ser. No. 63/772,801 filed on March 17, 2025, which application is incorporated herein by reference in its entirety.

Some references, which may include patents, patent applications and various publications, can be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an optical system and an optical method, and more particularly to an optical probe system and a calibration chuck thereof, a distance measuring method for at least one optical probe, a method of performing an optical testing on an electronic device under test, and an electronic device under test configured to be tested by the above-mentioned method.

### BACKGROUND OF THE DISCLOSURE

Referring to FIG. 1 and FIG. 2, in the related art, when using an optical probe P carried by a support arm R for testing a wafer W on an optical probe system (probe station), a distance sensor B carried by the support arm R is used to control the distance from an optical fiber F of the optical probe P to the wafer W. Therefore, it is necessary to first calibrate the fiber-to-sensor distance (D-d) between the optical fiber F and the distance sensor B. The so-called fiber-to-sensor distance (D-d) refers to a relative distance between a tip of the optical fiber F and the distance sensor B, which can be derived from the difference between a probe distance d measured from the optical fiber F to a chuck surface C11 and a sensor distance D measured from the distance sensor B to the chuck surface C11.

Referring to FIG. 2, the calibration method involves providing a flat chuck surface C11 and a 45-degree mirror C12 on the calibration chuck C of the optical probe system, and using a camera M located above to observe the optical fiber F through the 45-degree mirror C12. When the optical fiber F contacts the flat chuck surface C11, the fiber-to-sensor distance (D-d) between the optical fiber F and the distance sensor B can be obtained by the distance sensor B.

However, when the temperature of the wafer W changes at the optical test temperature in the optical probe system, the temperatures of the distance sensor B, the support arm R and the optical fiber F also change accordingly, causing them to contract (shrink) or expand (enlarge) in response to positive or negative temperature changes of the distance sensor B, the support arm R and the optical fiber F. That is to say, the fiber-to-sensor distance (D-d) measured at the optical test temperature is different from the fiber-to-sensor distance (D-d) measured at the room temperature due to thermal expansion and/or contraction of the various components of the optical probe system (and/or a probe assembly of the optical probe system).

More specifically, referring to FIG. 2, during temperature regulation, thermal expansion and/or contraction of the various components of the optical probe system may cause a relative distance (i.e., the fiber-to-sensor distance (D-d) between “a sensor distance D that is measured from the distance sensor B to the flat chuck surface C11 below” and “a probe distance d that is measured from the optical fiber F to the flat chuck surface C11 below” to be changed (due to the different thermal expansion coefficients (i.e., CTE) of the distance sensor B and/or the optical probe P). In other words, the difference between sensor distance D and the probe distance d may vary with temperature, but this distance variation may result in an inaccurate value for the fiber-to-sensor distance (D-d) that can be used in subsequent detection, determination, estimation, and/or calculation by the distance sensor B.

### SUMMARY OF THE DISCLOSURE

In order to solve the above-mentioned problems, a calibration chuck for an optical probe system can be equipped with a thermal control module to ensure that an optical probe calibrating environment (i.e., setting the calibration chuck to a simulated test temperature) and an optical probe measuring environment (i.e., setting the optical probe system or the thermal main chuck to an actual test temperature) can be provided to at least one optical probe at the same or similar temperatures, so that a calibrated fiber-to-sensor distance measured at a calibration temperature (the simulated test temperature) applied to the calibration chuck can remain consistent with a measured fiber-to-sensor distance measured at the actual test temperature applied to the thermal main chuck.

One of the technical aspects adopted by the present disclosure is to provide a calibration chuck for an optical probe system, which includes a calibration chuck body, an optical calibration structure and a thermal control module. The optical calibration structure is carried by the calibration chuck body, and the optical calibration structure is optionally configured to provide a viewing optical path for observation of at least one optical probe of the optical probe system. The thermal control module is thermally coupled to the calibration chuck body, and the thermal control module is optionally configured to provide a simulated test temperature environment applied to a calibration region of the calibration chuck to match an actual test temperature environment applied to the optical probe system. Therefore, a calibrated fiber-to-sensor distance measured at the simulated test temperature environment applied to the calibration chuck can remain consistent with a measured fiber-to-sensor distance measured at the actual test temperature environment applied to the optical probe system.

Another one of the technical aspects adopted by the present disclosure is to provide an optical probe system, which includes a thermal main chuck, a calibration chuck, a thermal control module and an optical probe assembly. The thermal main chuck is configured to carry at least one device under test (DUT). The calibration chuck includes a calibration chuck body and an optical calibration structure carried by the calibration chuck body. The thermal control module is thermally coupled to the thermal main chuck and the calibration chuck. The optical probe assembly is configured to be movably disposed adjacent to one of the thermal main chuck and the calibration chuck. The optical probe assembly includes at least one optical probe configured to be movably disposed adjacent to one of the thermal main chuck and the calibration chuck, and a distance sensor disposed adjacent to the at least one optical probe. The thermal control module is optionally configured to provide a simulated test temperature environment applied to the calibration chuck, and an actual test temperature environment applied to the thermal main chuck. Therefore, a calibrated fiber-to-sensor distance measured at the simulated test temperature environment applied to the calibration chuck can remain consistent with a measured fiber-to-sensor distance measured at the actual test temperature environment applied to the optical probe system.

Yet another one of the technical aspects of the present disclosure is to provide a distance measuring method for at least one optical probe provided by the above-mentioned optical probe system, which includes: positioning the at least one optical probe within the simulated test temperature environment applied to the calibration chuck; respectively obtaining a first vertical distance from the at least one optical probe to the calibration chuck, and a second vertical distance from a distance sensor to the calibration chuck, within the simulated test temperature environment applied to the calibration chuck; and calculating the difference between the first vertical distance and the vertical distance to obtain a minimum vertical distance between the distance sensor and a tip of the at least one optical probe. Therefore, a calibrated fiber-to-sensor distance measured at the simulated test temperature environment applied to the calibration chuck can be obtained accurately and quickly.

Yet another one of the technical aspects of the present disclosure is to provide a method of performing an optical testing on an electronic device under test, which includes providing the optical probe system by the above-mentioned optical probe system, positioning the optical probe assembly of the optical probe system in relation to the electronic device under test, and optically coupling the optical probe assembly to the electronic device under test to detect one of optical characteristics of the electronic device under test, and is to provide an electronic device under test configured to be tested by the above-mentioned method. Therefore, the optical probe system provided by the present disclosure can be configured to perform optical performance testing on the at least one electronic device under test.

In one of the feasible or preferred embodiments of the calibration chuck, the difference between two temperatures respectively obtained by at least one optical probe provided by the optical probe system and the optical calibration structure respectively from the thermal control module is within a predetermined range. Therefore, the thermal control module (such as a heater) can be configured as close to the optical probe as possible to shorten the distance between the thermal control module and the optical probe, so that the temperature gradient between the optical probe and the optical calibration structure can be reduced, and the temperature consistency between the optical probe and the optical calibration structure within the simulated test temperature environment applied to the calibration chuck can be improved, thereby ensuring the optical alignment and the distance measurement of the optical probe are more accurate during the actual testing within the actual test temperature environment applied to the optical probe system.

In one of the feasible or preferred embodiments of the calibration chuck, the optical calibration structure includes a light reflecting element (such as a mirror for providing a horizontal viewing function) disposed on a chuck surface of the calibration chuck body to provide a light reflecting surface, and the optical calibration structure is optionally configured to provide the viewing optical path through the light reflecting surface for an image capturing device provided by the optical probe system. Therefore, the image capturing device can be configured to observe at least one optical probe of the optical probe assembly through the light reflecting surface of the light reflecting element provided by the optical calibration structure.

In one of the feasible or preferred embodiments of the calibration chuck, the calibration chuck and a thermal main chuck provided by the optical probe system are separated from each other to respectively use two independent thermal control units of the thermal control module. Therefore, the thermal main chuck and the calibration chuck can be independently and respectively temperature-controlled by the two independent thermal control units provided by the thermal control module, thereby improving the flexibility (optionality) of the two independent thermal control units to perform independent temperature control operations according to different conditions or requirements.

In one of the feasible or preferred embodiments of the calibration chuck, the calibration chuck is carried by a thermal main chuck provided by the optical probe system, so that the thermal main chuck and the calibration chuck share the thermal control module. Therefore, the thermal main chuck and the calibration chuck can be synchronously temperature-controlled by the shared thermal control unit provided by the thermal control module, thereby improving the convenience (operability) of the shared thermal control unit to perform synchronous temperature control operations.

In one of the feasible or preferred embodiments of the calibration chuck, the optical calibration structure includes a top optical calibration unit disposed on a top side of the calibration chuck body and optionally configured to provide a top viewing optical path for a top image capturing device provided by the optical probe system. Alternatively, the optical calibration structure includes a bottom optical calibration structure disposed on a bottom side of the calibration chuck body and optionally configured to provide a bottom viewing optical path for a bottom image capturing device provided by the optical probe system. Therefore, the optical calibration structure (such as the top optical calibration unit and/or the bottom optical calibration structure) can be set in different positions (such as a top position and/or a bottom position) relative to the calibration chuck body according to different application requirements, thereby improving the flexibility (optionality) and the convenience (operability) of the optical calibration structure in use.

In one of the feasible or preferred embodiments of the calibration chuck, the thermal control module is optionally configured to regulate the simulated test temperature environment within a predefined temperature range to be substantially consistent with the actual test temperature environment. Therefore, the temperature difference between the simulated test temperature environment and the actual test temperature environment can be quickly corrected within the predetermined temperature range, thereby quickly adjusting or controlling the simulated test temperature environment and the actual test temperature environment to be consistent with each other.

In one of the feasible or preferred embodiments of the calibration chuck, the thermal control module includes a heating element and a cooling element disposed in the calibration chuck body to be optionally configured to provide the simulated test temperature environment applied to the calibration chuck. Therefore, the simulated test temperature environment applied to the calibration chuck can be precisely controlled by the heating element only or the cooperation of the heating element and the cooling element.

In one of the feasible or preferred embodiment of the optical probe system, the thermal main chuck is configured as a grid chuck having at least one through opening. Therefore, the thermal main chuck can be configured as a thermal double side chuck for the optical probe assembly to test the DUT from at least one of the top side and the bottom side of thermal main chuck, thereby improving the flexibility (optionality) and the convenience (operability) of using the thermal main chuck.

In one of the feasible or preferred embodiment of the optical probe system, the thermal control module includes a main thermal control unit thermally coupled to the thermal main chuck and an auxiliary thermal control unit thermally coupled to the calibration chuck, the thermal main chuck and the calibration chuck are separated from each other, and the main thermal control unit and the auxiliary thermal control unit are separated from each other. Therefore, the thermal main chuck and the calibration chuck can be independently and respectively temperature-controlled by the main thermal control unit and the auxiliary thermal control unit provided by the thermal control module, thereby improving the flexibility (optionality) of the main thermal control unit and the auxiliary thermal control unit to perform independent temperature control operations according to different conditions or requirements.

In one of the feasible or preferred embodiment of the optical probe system, the thermal control module includes a main thermal control unit thermally coupled to the thermal main chuck and the calibration chuck, the calibration chuck is carried by the thermal main chuck, and the thermal main chuck and the calibration chuck share the main thermal control unit of the thermal control module. Therefore, the thermal main chuck and the calibration chuck can be synchronously temperature-controlled by the shared main thermal control unit provided by the thermal control module, thereby improving the convenience (operability) of the shared main thermal control unit to perform synchronous temperature control operations.

In one of the feasible or preferred embodiment of the optical probe system, the optical probe assembly includes at least one top optical probe configured to be movably disposed above one of the thermal main chuck and the calibration chuck, and a top distance sensor disposed adjacent to the at least one top optical probe, the optical calibration structure includes a top optical calibration unit disposed on a top side of the calibration chuck body, the image capturing device includes a top image capturing unit configured to be movably disposed above the calibration chuck to vertically correspond to the top optical calibration unit of the calibration chuck, and the top image capturing device is optionally configured to observe the at least one top optical probe through a top viewing optical path provided by the top optical calibration unit. Alternatively, the optical probe assembly includes at least one bottom optical probe configured to be movably disposed below one of the thermal main chuck and the calibration chuck, and a bottom distance sensor disposed adjacent to the at least one bottom optical probe, the optical calibration structure includes a bottom optical calibration unit disposed on a bottom side of the calibration chuck body, the image capturing device includes a bottom image capturing unit configured to be movably disposed below the calibration chuck to vertically correspond to the bottom optical calibration unit of the calibration chuck, and the bottom image capturing device is optionally configured to observe the at least one bottom optical probe through a bottom viewing optical path provided by the bottom optical calibration unit. Therefore, the optical probe assembly (such as using the at least one top optical probe and the top distance sensor together, and/or using the at least one bottom optical probe and the bottom distance sensor together) can be set in different positions (such as a top position and/or a bottom position) relative to the thermal main chuck and/or the calibration chuck according to different application requirements, the optical calibration structure (such as the top optical calibration unit and/or the bottom optical calibration structure) can be set in different positions (such as a top position and/or a bottom position) relative to the calibration chuck body according to different application requirements, the image capturing device (such as the top image capturing unit and/or the bottom image capturing unit) can be set in different positions (such as a top position and/or a bottom position) relative to the calibration chuck according to different application requirements, thereby improving the flexibility (optionality) and the convenience (operability) of the optical probe assembly, the optical calibration structure and the image capturing device in use.

In one of the feasible or preferred embodiment of the optical probe system, the temperature difference between the simulated test temperature environment applied to the calibration chuck and the actual test temperature environment applied to the thermal main chuck is within 5%. Therefore, the temperature difference between the simulated test temperature environment and the actual test temperature environment can be quickly corrected within a temperature range of ±5%, thereby quickly adjusting or controlling the simulated test temperature environment and the actual test temperature environment to be consistent with each other.

In one of the feasible or preferred embodiment of the optical probe system, the optical probe assembly includes an environment temperature sensor disposed thereon to real-time monitor the simulated test temperature environment and the actual test temperature environment, and the thermal control module is optionally configured to regulate the simulated test temperature environment and the actual test temperature environment according to a real-time temperature feedback signal provided from the environment temperature sensor. Therefore, the simulated test temperature environment (such as the temperature of the calibration chuck) and the actual test temperature environment (such as the temperature of the thermal main chuck) can be monitored in real time by the environment temperature sensor to generate a real-time temperature feedback signal, and the simulated test temperature environment (such as the temperature of the calibration chuck) and the actual test temperature environment (such as the temperature of the thermal main chuck) can be dynamically adjusted according to the real-time temperature feedback signal provided from the environment temperature sensor, thereby improving the accuracy and the immediacy of adjusting the simulated test temperature environment (such as the temperature of the calibration chuck) and the actual test temperature environment (such as the temperature of the thermal main chuck).

These and other aspects of the present disclosure will become apparent from the following description of the embodiment taken in conjunction with the following drawings and their captions, although variations and modifications therein may be effected without departing from the spirit and scope of the novel concepts of the present disclosure.

### BRIEF DESCRIPTION OF THE DRAWINGS

The described embodiments may be better understood by reference to the following description and the accompanying drawings, in which:

FIG. 1 is a schematic view of an optical probe with a distance sensor applied to an optical probe system according to the related art;

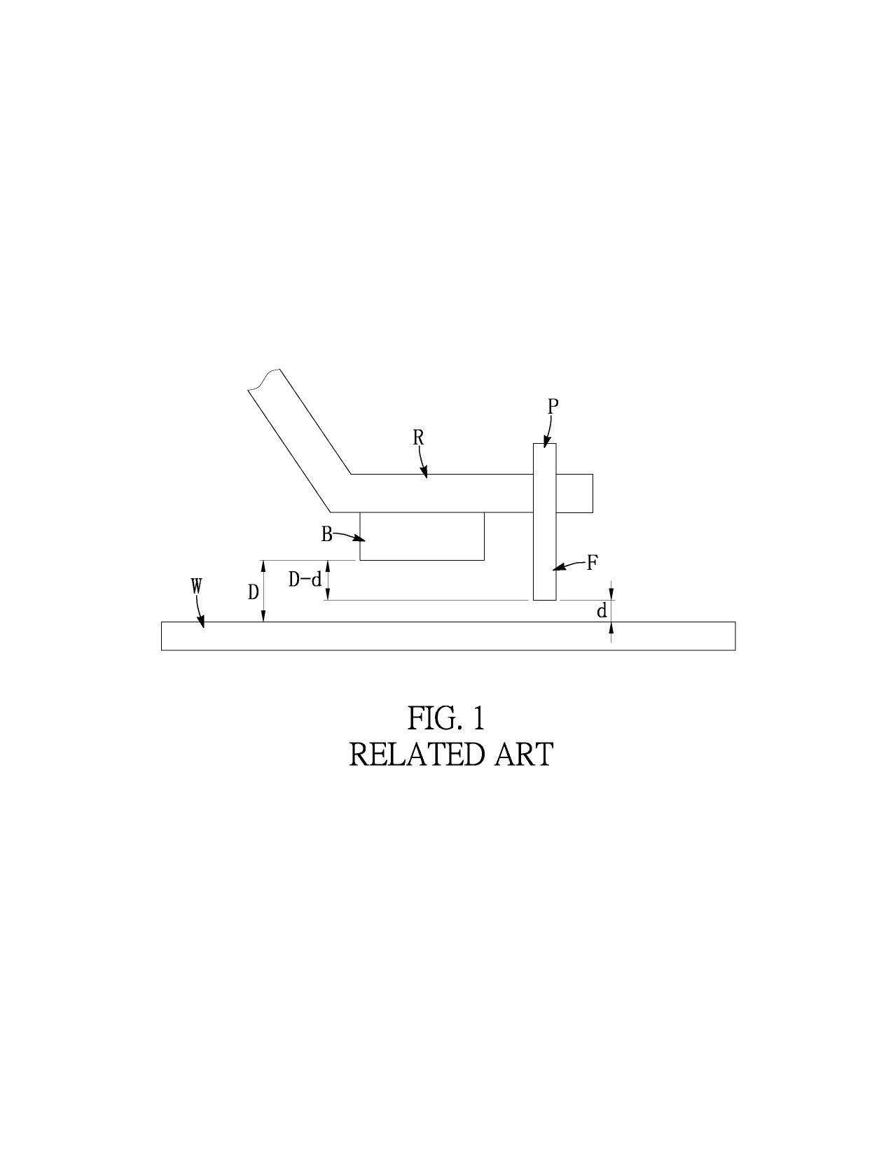

FIG. 2 is a schematic view of the optical probe with the distance sensor applied to a calibration chuck according to the related art;

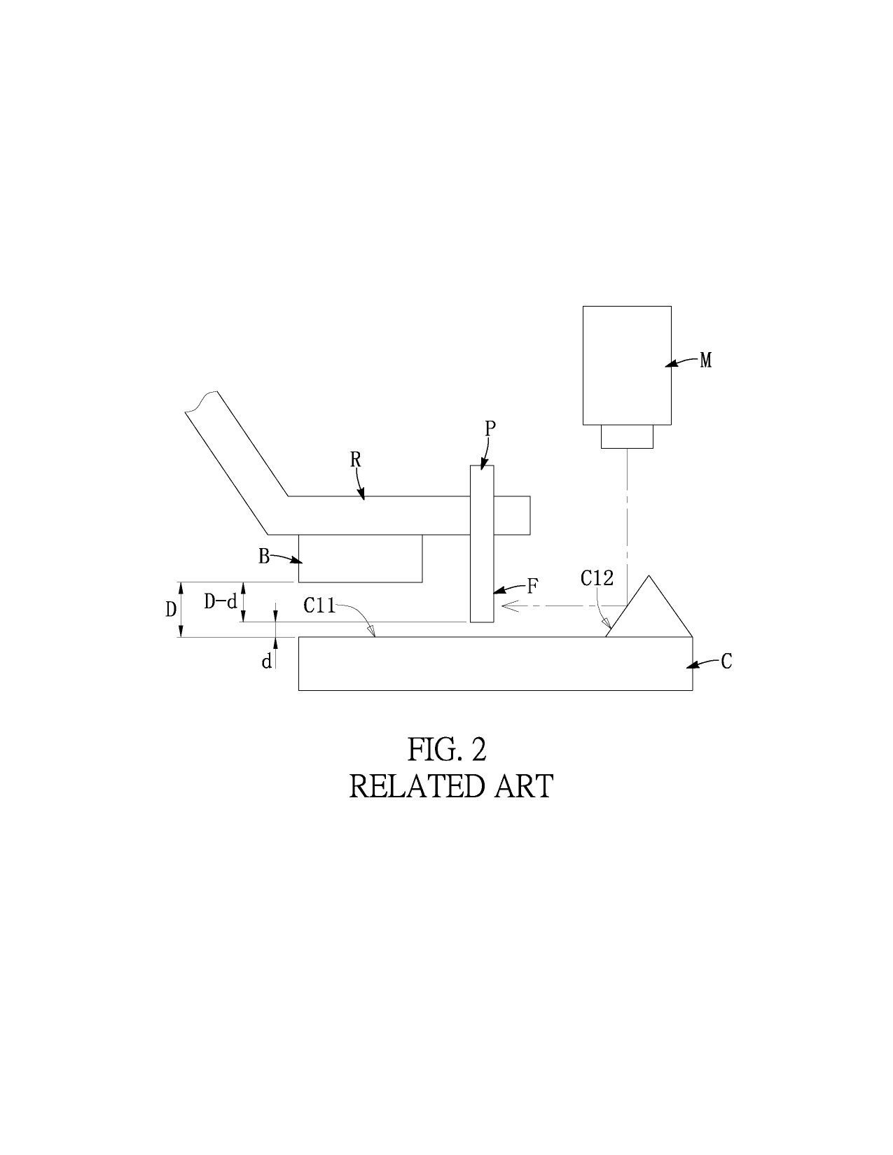

FIG. 3 is a schematic view of an optical probe system according to a first embodiment of the present disclosure;

FIG. 4 is a functional block diagram of an auxiliary thermal control unit provided by the optical probe system according to the first embodiment of the present disclosure;

FIG. 5 is a schematic view of the optical probe system according to a second embodiment of the present disclosure;

FIG. 6 is a functional block diagram of a main thermal control unit provided by the optical probe system according to the second embodiment of the present disclosure;

FIG. 7 is a schematic view of the optical probe system according to a third embodiment of the present disclosure;

FIG. 8 is a schematic view of the optical probe system according to a fourth embodiment of the present disclosure;

FIG. 9 is a schematic view of the optical probe system according to a fifth embodiment of the present disclosure;

FIG. 10 is a schematic view of the optical probe system according to a sixth embodiment of the present disclosure;

FIG. 11 is a schematic view of the optical probe system according to a seventh embodiment of the present disclosure;

FIG. 12 is a flowchart of a distance measuring method for at least one optical probe provided by the optical probe system according to an eighth embodiment of the present disclosure; and

FIG. 13 is a flowchart of a method of performing an optical testing on an electronic device under test according to a ninth embodiment of the present disclosure.

### DETAILED DESCRIPTION OF THE EXEMPLARY EMBODIMENTS

The present disclosure is more particularly described in the following embodiments and examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” may include plural reference, and the meaning of “in” may include “in” and “on.” Titles or subtitles can be used herein for the convenience of a reader, which shall have no influence on the scope of the present disclosure.

The terms used herein generally have their ordinary meanings in the art. In the case of conflict, the present document, may include any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification may include examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like. It should be noted that the examples described below are merely one feasible embodiment and are not intended to limit the scope of the present disclosure.

### First Embodiment

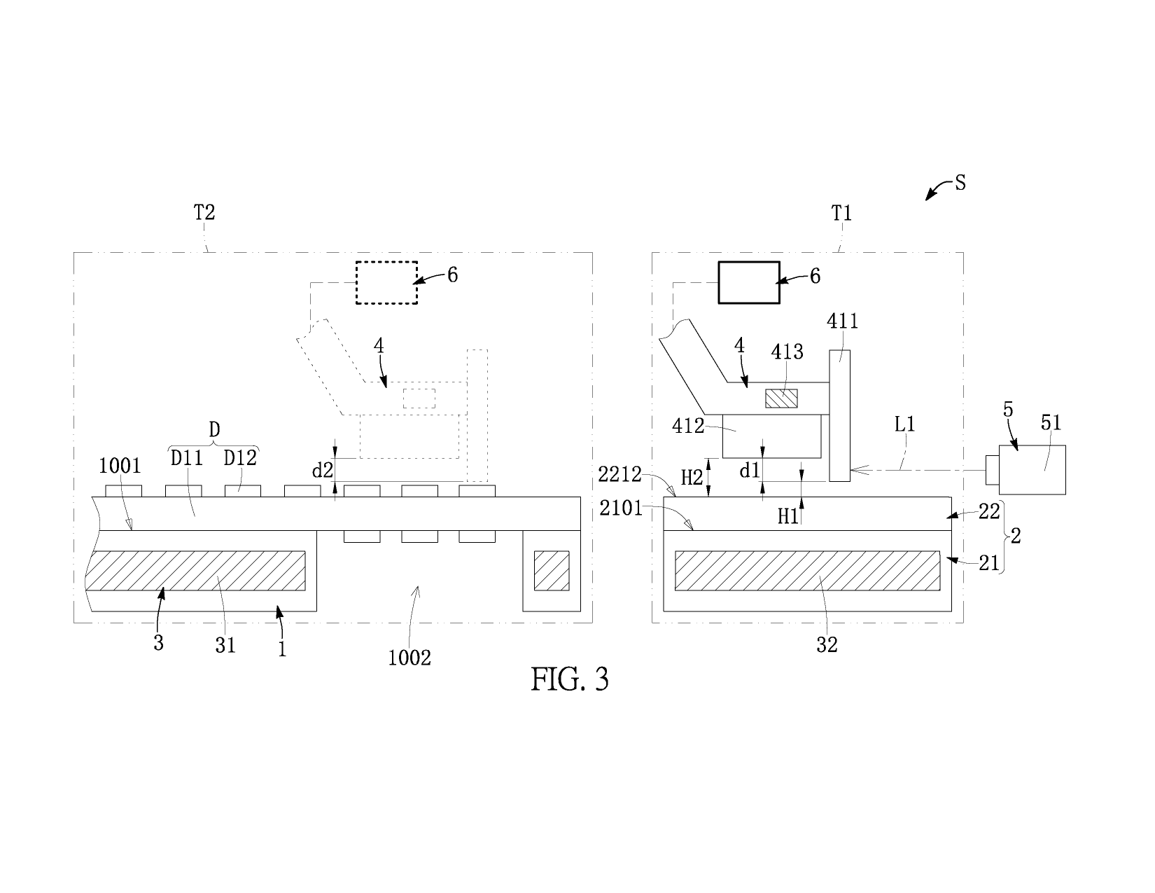

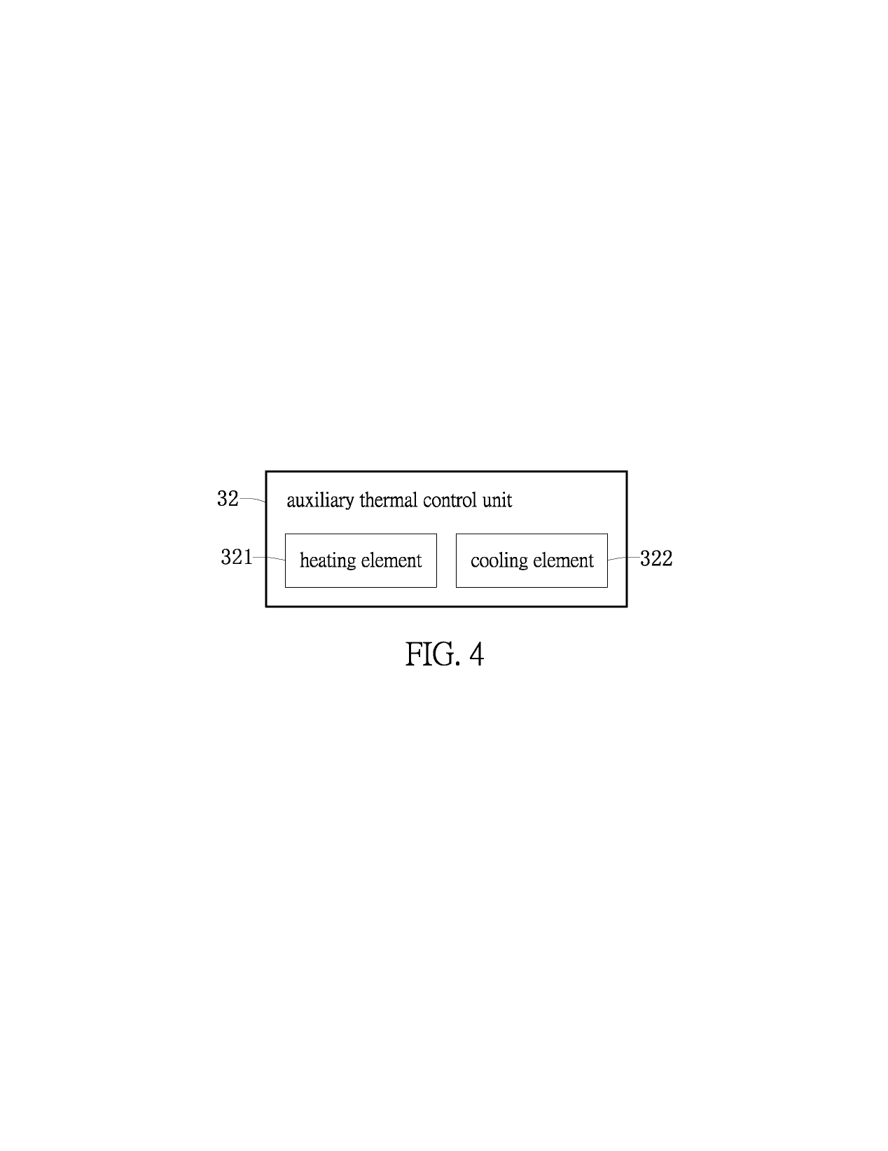

Referring to FIG. 3 and FIG. 4, a first embodiment of the present disclosure provides an optical probe system S, which may include a thermal main chuck 1, a calibration chuck 2, a thermal control module 3 and an optical probe assembly 4.

More particular, as shown in FIG. 3, the thermal main chuck 1 can be configured to carry or support at least one device under test D. For example, the thermal main chuck 1 may have a support surface 1001 that can be configured to support or carry the at least one device under test D that may include a device substrate D11 (such as silicon substrate or any type of material substrate) and a plurality of optical devices D12 (such as LED chips, photo diode chips, silicon photonics (SiPh) chips, VCSEL chips, laser diode chips, or any type of optical chips) disposed on the device substrate D11. Moreover, in one feasible embodiment, the thermal main chuck 1 can be configured as a grid chuck having at least one through opening 1002 (or a plurality of through openings 1002, or grid-like openings), or a solid chunk without any through opening (or grid-like opening) according to different requirements. Therefore, when the thermal main chuck 1 can be configured as a grid chuck, the thermal main chuck 1 can be configured as a thermal double side chuck for the optical probe assembly 4 to test the at least one device under test D from at least one of the top side and the bottom side of thermal main chuck 1, thereby improving the flexibility (optionality) and the convenience (operability) of using the thermal main chuck 1.

More particular, as shown in FIG. 3, the calibration chuck 2 may include a calibration chuck body 21 and an optical calibration structure 22 carried or supported by the calibration chuck body 21, in which the optical calibration structure 22 can be optionally (selectively) configured to provide a viewing optical path (i.e., observation means through optical path that can be defined as a defined optical viewing path) for observation (or inspection) of at least one optical probe of the optical probe system S. For example, in one feasible embodiment, the optical calibration structure 22 may include a top optical calibration unit that can be disposed on a top side of the calibration chuck body 21 and optionally configured to provide a top viewing optical path (such as a defined top optical viewing path). Moreover, the top optical calibration unit may include a light reflecting element (such as a mirror for providing a horizontal viewing function) disposed on a first chuck surface 2101 of the calibration chuck body 21 to provide a first light reflecting surface, so that the top optical calibration unit provided by the optical calibration structure 22 can be optionally configured to provide the top viewing optical path through the first light reflecting surface.

More particular, as shown in FIG. 3, the thermal control module 3 can be thermally coupled to (or structurally carried by) the thermal main chuck 1 and the calibration chuck 2. For example, in one feasible embodiment, the thermal control module 3 may include a main thermal control unit 31 (or first thermal control unit) thermally coupled to the thermal main chuck 1 and an auxiliary thermal control unit 32 (or second thermal control unit) thermally coupled to the calibration chuck 2 (or the calibration chuck body 21). Moreover, in one feasible embodiment, the main thermal control unit 31 and the auxiliary thermal control unit 32 can be separated from each other, so that the main thermal control unit 31 and the auxiliary thermal control unit 32 can be configured to supply (such as by transferring or radiating) heat source to the thermal main chuck 1 and the calibration chuck 2, respectively. In other words, the thermal main chuck 1 and the calibration chuck 2 provided by the optical probe system S can be separated (or thermally isolated) from each other to respectively use two independent thermal control units (i.e., the main thermal control unit 31 and the auxiliary thermal control unit 32 that can operate independently) of the thermal control module 3. Therefore, the thermal main chuck 1 and the calibration chuck 2 can be independently and respectively temperature-controlled by the main thermal control unit 31 and the auxiliary thermal control unit 32 provided by the thermal control module 3, thereby improving the flexibility (optionality) of the main thermal control unit 31 and the auxiliary thermal control unit 32 to perform independent temperature control operations according to different conditions or requirements. As used herein, the term “thermally coupled” refers to the arrangement or connection of two or more components that allows heat to be transferred between them through direct physical contact, indirect contact via an intermediate material, or thermal conduction via a structure or medium. For example, a thermal control module may be thermally coupled to a chuck body by means of a heat-conductive plate, a thermal interface material (TIM), or any other heat transfer element that allows thermal energy to flow between the components. The term does not necessarily require direct physical contact, as long as an effective thermal path is established to achieve temperature regulation or heat exchange between the thermally coupled components.

It should be noted that as shown in FIG. 3, the thermal control module 3 can be optionally (selectively) configured to provide a simulated test temperature environment (such as a first controllable temperature environment) applied to a calibration region T1 (such as an optical calibration space) of the calibration chuck 2 to substantially match (or conform to) an actual test temperature environment (such as a second controllable temperature environment) applied to a test region T2 (such as an optical and electrical test space) of the optical probe system S. In practical terms, the calibration chuck 2 is set to a calibration/test temperature (target temperature T’) by the thermal control module 3, which corresponds to the actual test temperature applied to the thermal main chuck 1. In other words, when the auxiliary thermal control unit 32 provided by the thermal control module 3 can be configured to provide the simulated test temperature environment applied to the calibration region T1 of the calibration chuck 2, the calibration region T1 can be defined around the calibration chuck 2, in particular above and below the calibration chuck 2. When the main thermal control unit 31 provided by the thermal control module 3 can be configured to provide the actual test temperature environment applied to the test region T2 of the optical probe system S, the test region T2 can be defined around thermal main chuck 1, in particular above and below the thermal main chuck 1. Therefore, a calibrated fiber-to-sensor distance d1 measured at the simulated test temperature environment applied to the calibration region T1 of the calibration chuck 2 can substantially remain consistent with (or conform to) a measured fiber-to-sensor distance d2 measured at the actual test temperature environment applied to the test region T2 of the optical probe system S, thereby ensuring consistency in the distance calibration between the calibrated fiber-to-sensor distance d1 and the measured fiber-to-sensor distance d2 under different thermal conditions.

For example, as shown in FIG. 3, in one feasible embodiment, the term “actual test temperature environment” can refer to that when the at least one device under test D is placed on the thermal main chuck 1, a real thermal environment can be applied to the thermal main chuck 1 during an optical or electrical testing process. In practical terms, the actual test temperature environment corresponds to the actual test temperature applied to the thermal main chuck 1. For example, when the at least one device under test D is required to be tested under a high temperature (such as 85°C), a low temperature condition (such as -40°C) or a room temperature, the actual test temperature environment can be defined as a corresponding thermal condition surrounding experienced by the at least one device under test D placed on the thermal main chuck 1 during the optical or electrical testing process.

For example, as shown in FIG. 3, in one feasible embodiment, the term “simulated test temperature environment” can refer to that the actual test temperature environment can be replicated or reproduced by applying a simulated thermal environment to the calibration chuck 2, which can be used for probe alignment, distance measurement, or optical path calibration without carrying at least one device under test D. In order to ensure the accuracy of calibration, the simulated test temperature environment can be regulated or adjusted by the thermal control module 3 to substantially match the actual test temperature environment that will then be applied to the at least one device under test D placed on the thermal main chuck 1 to perform the optical or electrical testing process.

By setting the calibration chuck 2 to a controlled calibration temperature that matches the actual test temperature, any thermal expansion, contraction, or drift of the optical probe assembly 4 and its associated components can be compensated during the calibration procedure. Therefore, when the optical probe assembly 4 is transferred from the calibration chuck 2 to the thermal main chuck 1 for actual testing, the positional accuracy, the optical alignment and the distance measurement of the optical probe assembly 4 can be maintained consistently under substantially the same thermal conditions at the simulated test temperature environment (applied to the calibration region T1 of the calibration chuck 2) and the actual test temperature environment (applied to the test region T2 of the optical probe system S).

For example, as shown in FIG. 3 and FIG. 4, in one feasible embodiment, the auxiliary thermal control unit 32 of the thermal control module 3 may include a heating element 321 (such as any type of heater) and/or a cooling element 322 (such as any type of cooler) that can be disposed (or embedded) in the calibration chuck body 21 (or disposed on the calibration chuck body 21) to be optionally configured to provide the simulated test temperature environment applied to the calibration region T1 of the calibration chuck 2. In other words, the auxiliary thermal control unit 32 of the thermal control module 3 may include a temperature control element (such as including the heating element 321 and/or the cooling element 322) disposed within the calibration chuck body 21, and the auxiliary thermal control unit 32 of the thermal control module 3 can be configured to regulate or adjust “the simulated test temperature environment that is applied to the calibration region T1 of the calibration chuck 2” to substantially correspond to “the actual test temperature environment that is applied to the test region T2 of the optical probe system S.” Therefore, the simulated test temperature environment applied to the calibration region T1 of the calibration chuck 2 can be precisely controlled by the heating element 321 only or the cooperation of the heating element 321 and the cooling element 322. It should be noted that in one feasible embodiment, the main thermal control unit 31 of the thermal control module 3 may include a heating element (not shown) and a cooling element (not shown) that can be disposed in the thermal main chuck 1 to be optionally configured to provide the actual test temperature environment applied to the test region T2 of the optical probe system S.

As mentioned above, for example, the following is a practical step to improve the calibration accuracy of the fiber-to-sensor distance (that is to say, the calibration environment can maintain the same or similar temperature conditions as the actual testing environment, ensuring that the measured distance between the optical probe (optical fiber) and the distance sensor is consistent under the calibration environment and the actual testing environment, thereby eliminating distance calibration errors caused by temperature differences):

1. Temperature settings for the thermal main chuck 1 and the calibration chuck 2: The thermal main chuck 1 and the calibration chuck 2 are set to the same target temperature T’ (i.e., the temperature of the DUT to be tested later) by heating and/or cooling. The temperature difference measurement and the temperature difference compensation for the optical probe are necessary due to potential temperature differences between the thermal main chuck 1 and the calibration chuck 2 during actual test operation. For example, even when the target temperatures of both the thermal main chuck 1 and the calibration chuck 2 are set to 100℃, the optical probe located above the thermal main chuck 1 or the calibration chuck 2 will experiences different amounts of heat (temperature) due to the different thicknesses and thermal conductivity of the wafer (the thermal main chuck 1) and the optical calibration structure 22 (the calibration chuck 2).

2. Measurement of the temperature difference between the optical probe above the thermal main chuck 1 and the calibration chuck 2: The temperature Tw above the wafer surface (the thermal main chuck 1) and the temperature Tc above the mirror (the calibration chuck 2) are measured by using the temperature sensor on the optical probe, and then the difference (Tw–Tc=dT) between temperature Tw and temperature Tc is calculated to obtain the temperature compensation parameters.

3. Temperature compensation and consistency adjustment: The temperature of the thermal main chuck 1 or the calibration chuck 2 are adjusted to ensure the actual wafer testing environment (Tw) are consistent with the calibration environment (Tc), thereby achieving temperature uniformity between the calibration environment (i.e., the simulated test temperature environment) and the actual testing environment (i.e., the actual test temperature environment).

4. Once the temperatures of the calibration environment and the actual testing environment are consistent, the calibration of the fiber-to-sensor distance (D-d) can be performed.

It should be noted that whether calibrating or testing the optical probe, after moving the optical probe to the thermal main chuck 1 or the calibration chuck 2, the optical probe will not be calibrated or tested immediately, but only after the optical probe has been soaked or left to stand for a period of time. That is to say, a period of time will be allowed for the optical probe to reach thermal equilibrium (thermal stability) before performing the calibration or testing of the optical probe.

It should be noted that as shown in FIG. 3, the main thermal control unit 31 and the auxiliary thermal control unit 32 provided by the thermal control module 3 can be optionally configured to regulate (or control) the simulated test temperature environment (applied to the calibration region T1 of the calibration chuck 2) within a predefined temperature range (or a predefined tolerance range) to be substantially consistent with the actual test temperature environment (applied to the test region T2 of the optical probe system S). Therefore, the temperature difference between the simulated test temperature environment and the actual test temperature environment can be quickly corrected (or calibrated) within the predetermined temperature range, thereby quickly adjusting or controlling the simulated test temperature environment and the actual test temperature environment to be substantially consistent with each other. For example, in one feasible embodiment, the temperature difference between the simulated test temperature environment applied to the calibration region T1 of the calibration chuck 2 and the actual test temperature environment applied to the test region T2 of the thermal main chuck 1 can be within 5% (such as within the predefined tolerance range of plus or minus 5℃). Therefore, the temperature difference between the simulated test temperature environment within the calibration region T1 and the actual test temperature environment within the test region T2 can be quickly corrected (or calibrated) within a temperature range of ±5%, thereby quickly adjusting or controlling the simulated test temperature environment and the actual test temperature environment to be substantially consistent with each other.

It should be noted that, for example, the term “substantially consistent” between the simulated test temperature environment and the actual test temperature environment as used in the present disclosure may mean that the temperature conditions applied to the calibration chuck 2 and to the thermal main chuck 1 are maintained within a predetermined tolerance to prevent significant thermal mismatch or thermal deviation. In some embodiments, the term “substantially consistent” may mean that the temperature difference between the simulated test temperature environment and the actual test temperature environment is less than approximately ±5°C of the actual test temperature environment, or less than approximately ±3°C in practical applications. The above definition of the term “substantially consistent” can ensure that any thermal expansion, contraction, or drift of the optical probe assembly 4, the calibration chuck 2, and the thermal main chuck 1 is effectively compensated during calibration, thereby enabling the alignment and distance measurement accuracy obtained by the optical probe assembly 4 above the calibration chuck 2 to be reliably applied to the testing of the at least one device under test D placed on the thermal main chuck 1.

More particularly, as shown in FIG. 3, the optical probe assembly 4 can be configured to be movably disposed adjacent to (such as disposed above) one of the thermal main chuck 1 and the calibration chuck 2 (for the convenience of explanation, FIG. 4 shows two optical probe assemblies 4 formed by solid and dashed lines and corresponding to two different situations adjacent to the thermal main chuck 1 and the calibration chuck 2, respectively; however, in practice, there is actually only one optical probe assembly 4, which is positioned either above the thermal main chuck 1 or the calibration chuck 2 to respectively perform electrical testing or optical calibration). For example, in one feasible embodiment, the optical probe assembly 4 may include at least one top optical probe 411 that can be configured to be movably disposed above one of the thermal main chuck 1 and the calibration chuck 2, and a top distance sensor 412 that can be disposed adjacent to the at least one top optical probe 411. Moreover, the optical probe assembly 4 may further include an environment temperature sensor (such as a top environment temperature sensor 413) disposed thereon to real-time monitor (or control) the simulated test temperature environment within the calibration region T1 and the actual test temperature environment within the test region T2, so that the thermal control module 3 can be optionally configured to regulate (or control) the simulated test temperature environment within the calibration region T1 and the actual test temperature environment within the test region T2 according to a real-time temperature feedback signal provided from the top environment temperature sensor 413. Therefore, the simulated test temperature environment (applied to the calibration region T1 of the calibration chuck 2) and the actual test temperature environment (applied to the test region T2 of the optical probe system S) can be monitored in real time by the top environment temperature sensor 413 to generate a real-time temperature feedback signal, and the simulated test temperature environment within the calibration region T1 and the actual test temperature environment within the test region T2 can be dynamically adjusted or regulated according to the real-time temperature feedback signal provided from the top environment temperature sensor 413, thereby improving the accuracy and the immediacy of adjusting or regulating the simulated test temperature environment within the calibration region T1 and the actual test temperature environment within the test region T2. As used herein, the term “adjacent to” refers to a spatial relationship in which two elements are positioned next to, near, or in proximity to each other, with or without direct physical contact. For example, an optical probe may be described as being “adjacent to” a calibration chuck when it is disposed above or close to the calibration chuck at a distance sufficient to allow optical measurement, thermal interaction, or alignment. Therefore, the term “adjacent to” encompasses both direct contact and slight spacing between elements, as long as their relative positions enable the intended optical, thermal, or mechanical functions described in the present disclosure.

For example, as shown in FIG. 3, in one feasible embodiment, the difference between two temperatures respectively obtained by the at least one top optical probe 411 provided by the optical probe assembly 4 and the optical calibration structure 22 provided by the calibration chuck 2 respectively from the auxiliary thermal control unit 32 of the thermal control module 3 is within a predetermined range (such as within a predefined tolerance range of 10%). Therefore, the auxiliary thermal control unit 32 of the thermal control module 3 can be configured as close to the at least one top optical probe 411 as possible to shorten the distance between the auxiliary thermal control unit 32 and the at least one top optical probe 411, so that the temperature gradient between the at least one top optical probe 411 and the optical calibration structure 22 can be reduced, and the temperature consistency between the at least one top optical probe 411 and the optical calibration structure 22 within the simulated test temperature environment applied to the calibration region T1 of the calibration chuck 2 can be improved, thereby ensuring the optical alignment and the distance measurement of the at least one top optical probe 411 are more accurate during the actual testing within the actual test temperature environment applied to the test region T2 of the thermal main chuck 1.

More particularly, as shown in FIG. 3, the optical probe system S may further include an image capturing device 5 that can be configured to be movably disposed adjacent to the calibration chuck 2, and the image capturing device 5 can be optionally (selectively) configured to observe the optical probe assembly 4 through a viewing optical path (or a defined optical viewing path) provided by the optical calibration structure 22, or the image capturing device 5 can be optionally (selectively) configured to observe the optical probe assembly 4 through a first side-viewing optical path L1 (such as a first horizontal side-viewing optical path, or a first oblique side-viewing optical path). For example, in one feasible embodiment, the image capturing device 5 (such as a camera) may include a top image capturing unit 51 (such as including a CCD image sensor, a CMOS image sensor or any type of image sensor that can be placed in a portrait orientation for capturing images along a vertical direction, a landscape orientation for capturing images along a horizontal direction, or a tilted orientation for capturing images along an oblique direction) that can be configured to be movably disposed adjacent or next to the calibration chuck 2, or configured to be movably disposed above the calibration chuck 2 to vertically correspond to the first light reflecting surface of the top optical calibration unit provided by the calibration chuck 2. Therefore, when the optical probe assembly 4 can be configured to be movably disposed above the calibration chuck 2 (or movably disposed within the calibration region T1 of the calibration chuck 2), the optical calibration structure 22 can be optionally configured to provide the top viewing optical path through the first light reflecting surface of the top optical calibration unit for the top image capturing device 51, so that the top image capturing device 51 can be optionally configured to observe a tip of the at least one top optical probe 411 through the top viewing optical path provided by the first light reflecting surface of the top optical calibration unit. It should be noted that the top viewing optical path (or defined top optical viewing path) provided by the top optical calibration unit can be defined as follows: the light reflecting element (such as a reflector having a mirror surface) provided by the top optical calibration unit can be positioned by a specific angle (such as 45° or any acute angle) to provide a predetermined visual path (or predetermined observation angle) for the top image capturing device 51, and the relative position between the at least one top optical probe 411 and the top image capturing device 51 can depend on the predetermined visual path (or predetermined observation angle).

More particularly, as shown in FIG. 3, the optical probe system S may further include a signal generation and analysis module 6 that can be optionally (selectively) configured to provide an optical test signal to the optical probe assembly 4 or receive an optical resultant signal from the optical probe assembly 4. For example, in one feasible embodiment, the signal generation and analysis module 6 (such as signal control module) may be a desktop computer, a laptop computer, a tablet computer or any type of portable electronic device that may include a central processing unit (CPU), a digital signal processor (DSP), a microprocessor (MPU), a microcontroller (MCU) or any type of signal control chip.

### Second Embodiment

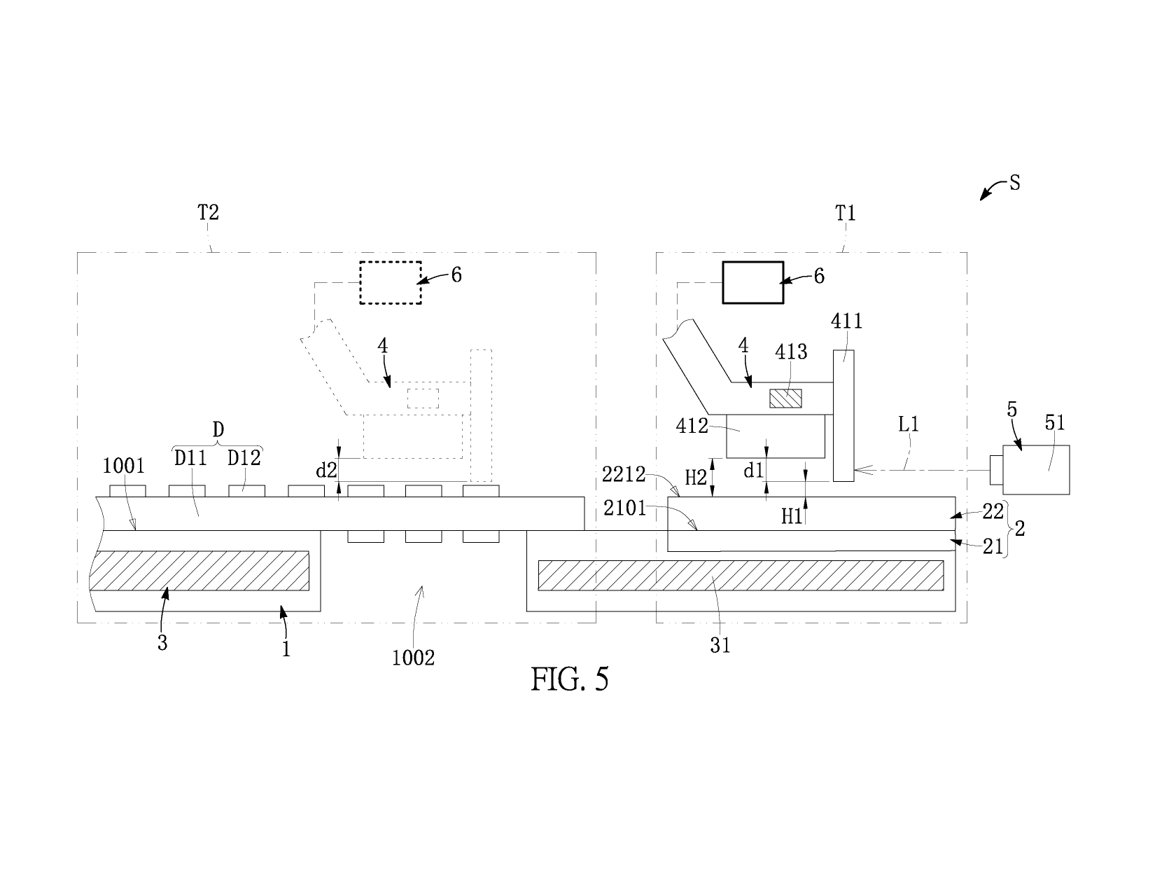

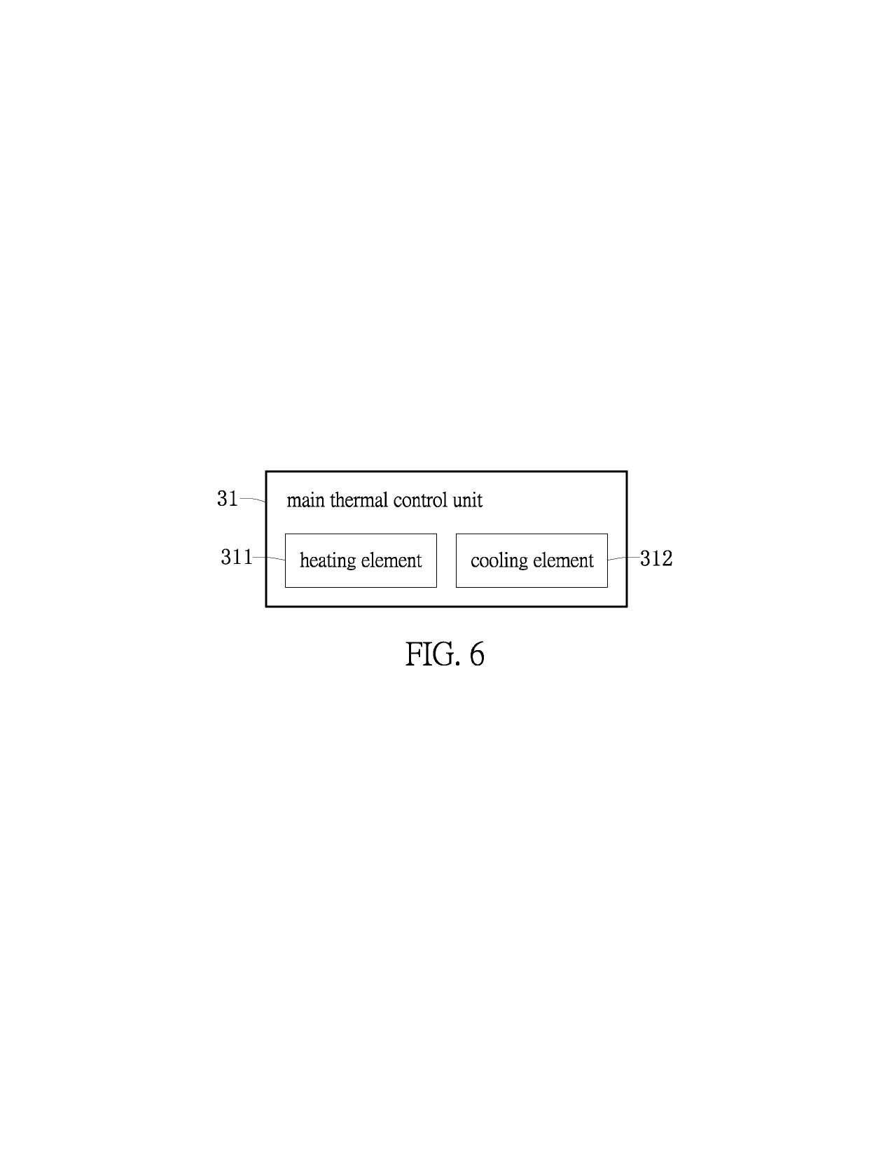

Referring to FIG. 5 to FIG. 6, a second embodiment of the present disclosure provides an optical probe system S, which may include a thermal main chuck 1, a calibration chuck 2, a thermal control module 3 and an optical probe assembly 4. Comparing FIG. 5 with FIG. 3, and comparing FIG. 6 with FIG. 4, the main difference between the second embodiment and the first embodiment is as follows:

For example, as shown in FIG. 5, in one feasible embodiment, the thermal control module 3 may include a main thermal control unit 31 (i.e., a shared thermal control unit) thermally coupled to the thermal main chuck 1 and the calibration chuck 2, and the thermal main chuck 1 and the calibration chuck 2 can share the main thermal control unit 31 of the thermal control module 3. More particular, the calibration chuck 2 can be carried or supported by the thermal main chuck 1, so that the thermal main chuck 1 and the calibration chuck 2 can share the thermal control module 3 (In other word, when the calibration chuck 2 is mounted on the thermal main chuck 1, and the thermal control module 3 may include a main thermal control unit 31 shared between the calibration chuck 2 and the thermal main chuck 1). Therefore, the thermal main chuck 1 and the calibration chuck 2 can be synchronously temperature-controlled by the shared main thermal control unit 31 provided by the thermal control module 3, thereby improving the convenience (operability) of the shared main thermal control unit 31 to perform synchronous temperature control operations.

For example, referring to FIG. 5 and FIG. 6, in one feasible embodiment, the main thermal control unit 31 of the thermal control module 3 may include a heating element 311 (such as any type of heater) and a cooling element 312 (such as any type of cooler) that can be disposed (or embedded) in the thermal main chuck 1 (or disposed on the thermal main chuck 1) to be optionally configured to provide the actual test temperature environment applied to the test region T2 of the optical probe system S. Therefore, the actual test temperature environment applied to the test region T2 of the optical probe system S can be precisely controlled by the heating element 311 only or the cooperation of the heating element 311 and the cooling element 312.

### Third Embodiment

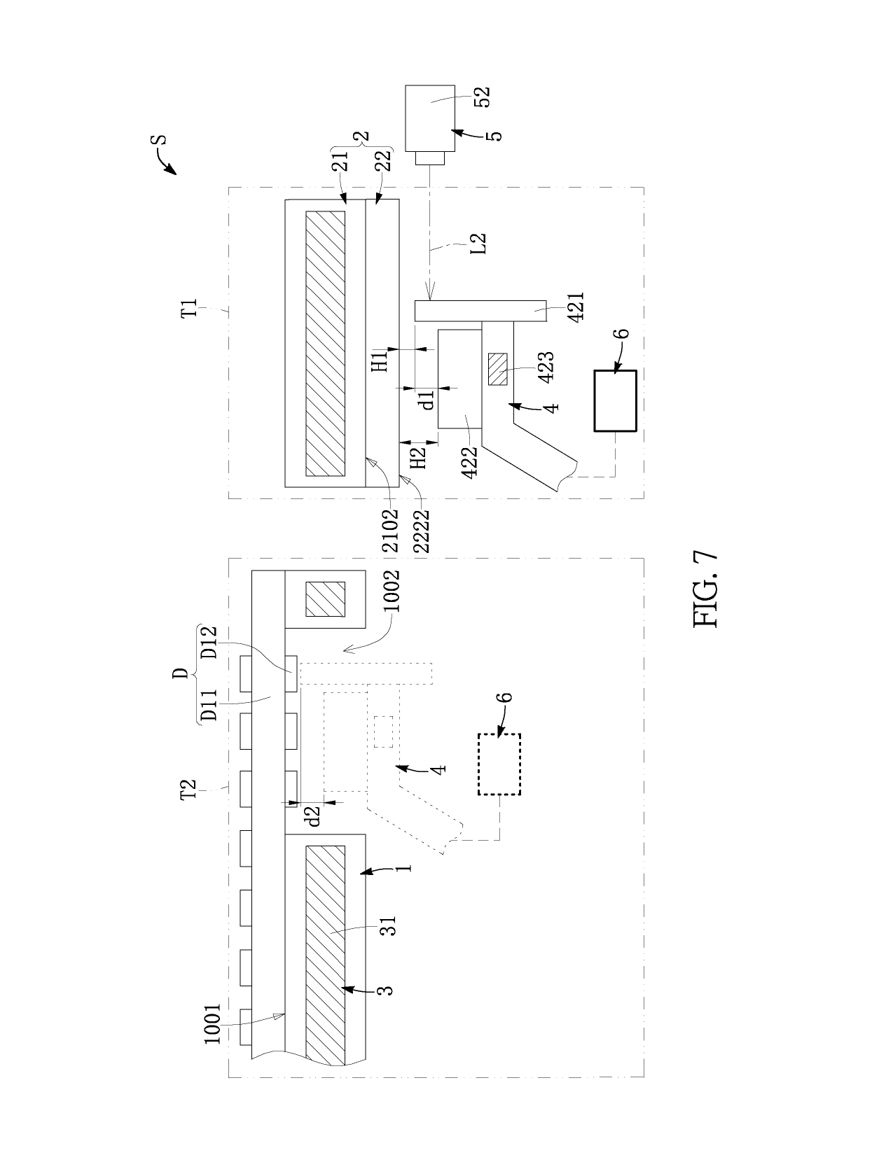

Referring to FIG. 7, a third embodiment of the present disclosure provides an optical probe system S, which may include a thermal main chuck 1, a calibration chuck 2, a thermal control module 3 and an optical probe assembly 4. Comparing FIG. 7 with FIG. 3, the main difference between the third embodiment and the first embodiment is as follows:

For example, as shown in FIG. 7, in one feasible embodiment, the optical calibration structure 22 may include a bottom optical calibration unit that can be disposed on a bottom side of the calibration chuck body 21 and optionally configured to provide a bottom viewing optical path (such as a defined bottom optical viewing path). Moreover, the bottom optical calibration unit may include a light reflecting element (such as a mirror for providing a horizontal viewing function) disposed on a second chuck surface 2102 of the calibration chuck body 21 to provide a second light reflecting surface, so that the bottom optical calibration unit provided by the optical calibration structure 22 can be optionally configured to provide the bottom viewing optical path through the second light reflecting surface.

For example, as shown in FIG. 7, in one feasible embodiment, the optical probe assembly 4 may include at least one bottom optical probe 421 that can be configured to be movably disposed below one of the thermal main chuck 1 and the calibration chuck 2, and a bottom distance sensor 422 that can be disposed adjacent to the at least one bottom optical probe 421. Moreover, the optical probe assembly 4 may further include another environment temperature sensor (such as a bottom environment temperature sensor 423) disposed thereon to real-time monitor (or control) the simulated test temperature environment within the calibration region T1 and the actual test temperature environment within the test region T2, so that the thermal control module 3 can be optionally configured to regulate (or control) the simulated test temperature environment within the calibration region T1 and the actual test temperature environment within the test region T2 according to a real-time temperature feedback signal provided from the bottom environment temperature sensor 423. Therefore, the simulated test temperature environment (applied to the calibration region T1 of the calibration chuck 2) and the actual test temperature environment (applied to the test region T2 of the optical probe system S) can be monitored in real time by the bottom environment temperature sensor 423 to generate a real-time temperature feedback signal, and the simulated test temperature environment within the calibration region T1 and the actual test temperature environment within the test region T2 can be dynamically adjusted or regulated according to the real-time temperature feedback signal provided from the bottom environment temperature sensor 423, thereby improving the accuracy and the immediacy of adjusting or regulating the simulated test temperature environment within the calibration region T1 and the actual test temperature environment within the test region T2.

For example, as shown in FIG. 7, in one feasible embodiment, the image capturing device 5 can also be optionally (selectively) configured to observe the optical probe assembly 4 through a second side-viewing optical path L2 (such as a second horizontal side-viewing optical path, or a second oblique side-viewing optical path). More particularly, the image capturing device 5 may include a bottom image capturing unit 52 (such as including a CCD image sensor, a CMOS image sensor or any type of image sensor that can be placed in a portrait orientation for capturing images along a vertical direction, a landscape orientation for capturing images along a horizontal direction, or a tilted orientation for capturing images along an oblique direction) that can be configured to be movably disposed adjacent or next to the calibration chuck 2, or configured to be movably disposed below the calibration chuck 2 to vertically correspond to the second light reflecting surface of the bottom optical calibration unit provided by the calibration chuck 2. Therefore, when the optical probe assembly 4 can be configured to be movably disposed below the calibration chuck 2 (or movably disposed within the calibration region T1 of the calibration chuck 2), the optical calibration structure 22 can be optionally configured to provide the bottom viewing optical path through the second light reflecting surface of the bottom optical calibration unit for the bottom image capturing device 52, so that the bottom image capturing device 52 can be optionally configured to observe a tip of the at least one bottom optical probe 421 through the bottom viewing optical path provided by the second light reflecting surface of the bottom optical calibration unit. It should be noted that the bottom viewing optical path (or defined bottom optical viewing path) provided by the bottom optical calibration unit can be defined as follows: the light reflecting element (such as a reflector having a mirror surface) provided by the bottom optical calibration unit can be positioned by a specific angle (such as 45° or any acute angle) to provide a predetermined visual path (or predetermined observation angle) for the bottom image capturing device 52, and the relative position between the at least one bottom optical probe 421 and the bottom image capturing device 52 can depend on the predetermined visual path (or predetermined observation angle).

### Fourth Embodiment

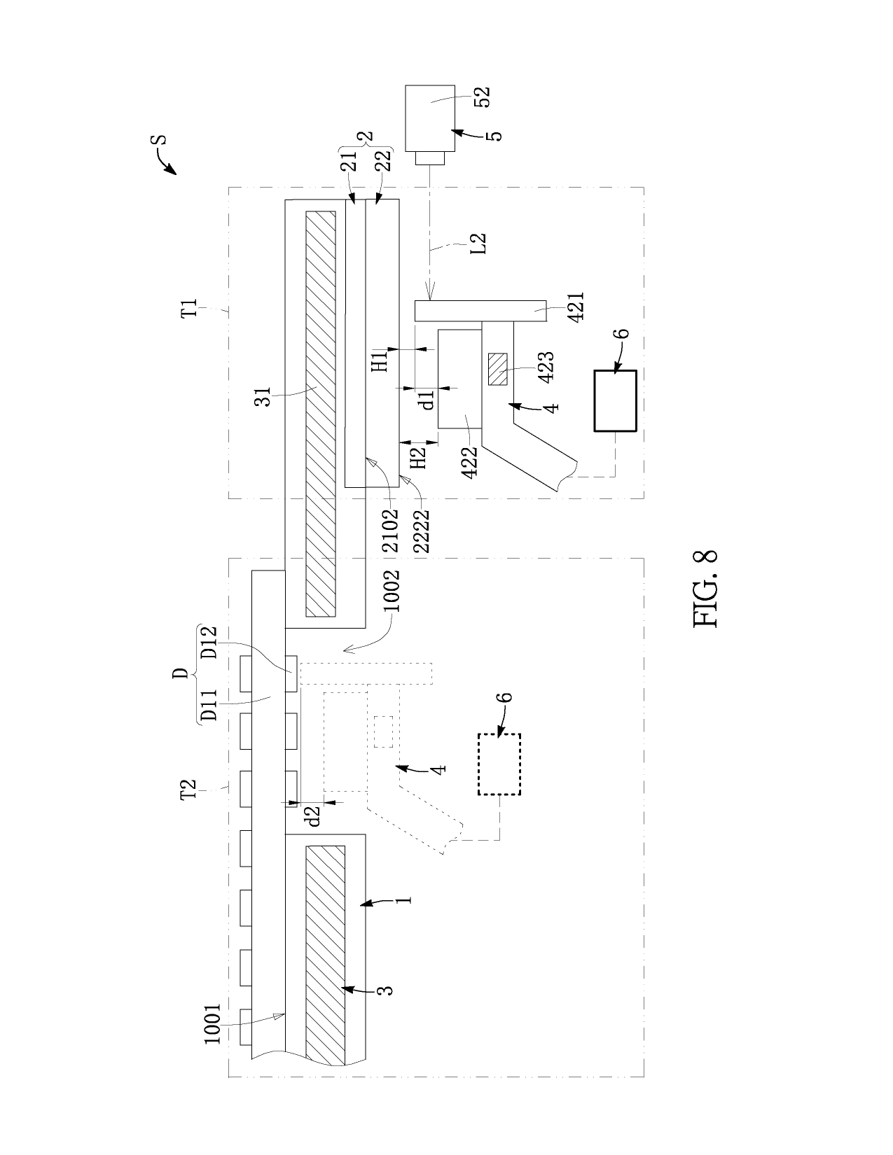

Referring to FIG. 8, a fourth embodiment of the present disclosure provides an optical probe system S, which may include a thermal main chuck 1, a calibration chuck 2, a thermal control module 3 and an optical probe assembly 4. Comparing FIG. 8 with FIG. 7, the main difference between the fourth embodiment and the third embodiment is as follows:

For example, as shown in FIG. 8, in one feasible embodiment, the thermal control module 3 may include a main thermal control unit 31 (i.e., a shared thermal control unit) thermally coupled to the thermal main chuck 1 and the calibration chuck 2, and the thermal main chuck 1 and the calibration chuck 2 can share the main thermal control unit 31 of the thermal control module 3. More particular, the calibration chuck 2 can be carried or supported by the thermal main chuck 1, so that the thermal main chuck 1 and the calibration chuck 2 can share the thermal control module 3 (In other word, when the calibration chuck 2 is mounted on the thermal main chuck 1, and the thermal control module 3 may include a main thermal control unit 31 shared between the calibration chuck 2 and the thermal main chuck 1). Therefore, the thermal main chuck 1 and the calibration chuck 2 can be synchronously temperature-controlled by the shared main thermal control unit 31 provided by the thermal control module 3, thereby improving the convenience (operability) of the shared main thermal control unit 31 to perform synchronous temperature control operations.

For example, as shown in FIG. 8, in one feasible embodiment, the main thermal control unit 31 of the thermal control module 3 may include a heating element 311 (such as any type of heater) and a cooling element 312 (such as any type of cooler) that can be disposed (or embedded) in the thermal main chuck 1 (or disposed on the thermal main chuck 1) to be optionally configured to provide the actual test temperature environment applied to the test region T2 of the optical probe system S. Therefore, the actual test temperature environment applied to the test region T2 of the optical probe system S can be precisely controlled by the heating element 311 only or the cooperation of the heating element 311 and the cooling element 312.

### Fifth Embodiment

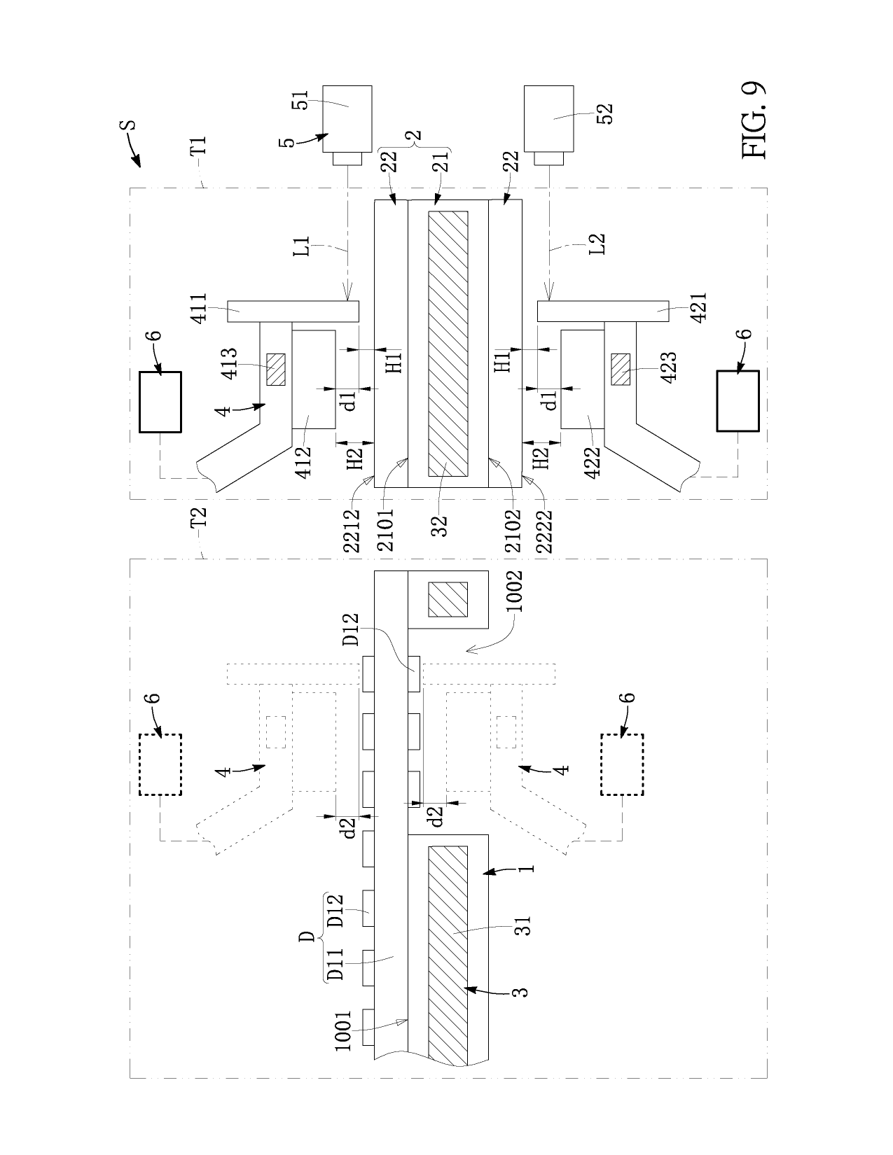

Referring to FIG. 9, a fifth embodiment of the present disclosure provides an optical probe system S, which may include a thermal main chuck 1, a calibration chuck 2, a thermal control module 3 and an optical probe assembly 4. Comparing FIG. 9 with FIG. 3 and FIG. 7, the main difference between the fifth embodiment and the first and second embodiments is as follows:

For example, as shown in FIG. 9, in one feasible embodiment, the optical calibration structure 22 may include a top optical calibration unit that can be disposed on a top side of the calibration chuck body 21 and optionally configured to provide a top viewing optical path. More particularly, the optical calibration structure 22 may further include a bottom optical calibration unit that can be disposed on a bottom side of the calibration chuck body 21 and optionally configured to provide a bottom viewing optical path.

For example, as shown in FIG. 9, in one feasible embodiment, the optical probe assembly 4 may include at least one top optical probe 411 that can be configured to be movably disposed above one of the thermal main chuck 1 and the calibration chuck 2, and a top distance sensor 412 that can be disposed adjacent to the at least one top optical probe 411. More particularly, the optical probe assembly 4 may further include at least one bottom optical probe 421 that can be configured to be movably disposed below one of the thermal main chuck 1 and the calibration chuck 2, and a bottom distance sensor 422 that can be disposed adjacent to the at least one bottom optical probe 421.

For example, as shown in FIG. 9, in one feasible embodiment, the image capturing device 5 may include a top image capturing unit 51 that can be configured to be movably disposed above the calibration chuck 2 to vertically correspond to the first light reflecting surface of the top optical calibration unit provided by the calibration chuck 2. More particularly, the image capturing device 5 may further include a bottom image capturing unit 52 that can be configured to be movably disposed below the calibration chuck 2 to vertically correspond to the second light reflecting surface of the bottom optical calibration unit provided by the calibration chuck 2.

Therefore, the optical probe assembly 4 (such as using the at least one top optical probe 411 and the top distance sensor 412 together, and/or using the at least one bottom optical probe 421 and the bottom distance sensor 422 together) can be set in different positions (such as a top position and/or a bottom position) relative to the thermal main chuck 1 and/or the calibration chuck 2 according to different application requirements, the optical calibration structure 22 (such as the top optical calibration unit and/or the bottom optical calibration structure) can be set in different positions (such as a top position and/or a bottom position) relative to the calibration chuck body 21 according to different application requirements, the image capturing device 5 (such as the top image capturing unit 51 and/or the bottom image capturing unit 52) can be set in different positions (such as a top position and/or a bottom position) relative to the calibration chuck 2 according to different application requirements, thereby improving the flexibility (optionality) and the convenience (operability) of the optical probe assembly 4, the optical calibration structure 22 and the image capturing device 5 in use.

### Sixth Embodiment

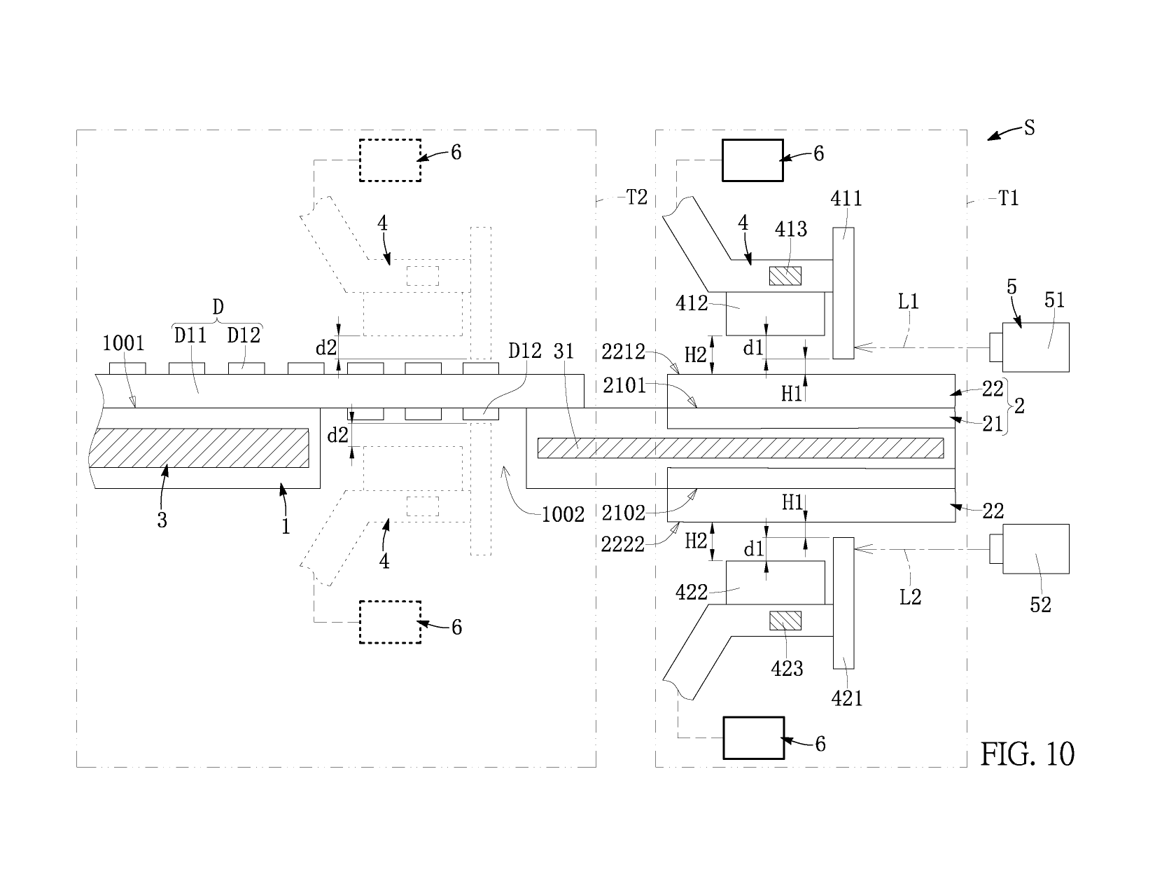

Referring to FIG. 10, a sixth embodiment of the present disclosure provides an optical probe system S, which may include a thermal main chuck 1, a calibration chuck 2, a thermal control module 3 and an optical probe assembly 4. Comparing FIG. 10 with FIG. 9, the main difference between the sixth embodiment and the fifth embodiment is as follows:

For example, as shown in FIG. 10, in one feasible embodiment, the thermal control module 3 may include a main thermal control unit 31 (i.e., a shared thermal control unit) thermally coupled to the thermal main chuck 1 and the calibration chuck 2, and the thermal main chuck 1 and the calibration chuck 2 can share the main thermal control unit 31 of the thermal control module 3. More particular, the calibration chuck 2 can be carried or supported by the thermal main chuck 1, so that the thermal main chuck 1 and the calibration chuck 2 can share the thermal control module 3 (In other word, when the calibration chuck 2 is mounted on the thermal main chuck 1, and the thermal control module 3 may include a main thermal control unit 31 shared between the calibration chuck 2 and the thermal main chuck 1). Therefore, the thermal main chuck 1 and the calibration chuck 2 can be synchronously temperature-controlled by the shared main thermal control unit 31 provided by the thermal control module 3, thereby improving the convenience (operability) of the shared main thermal control unit 31 to perform synchronous temperature control operations.

For example, as shown in FIG. 10, in one feasible embodiment, the main thermal control unit 31 of the thermal control module 3 may include a heating element 311 (such as any type of heater) and a cooling element 312 (such as any type of cooler) that can be disposed (or embedded) in the thermal main chuck 1 (or disposed on the thermal main chuck 1) to be optionally configured to provide the actual test temperature environment applied to the test region T2 of the optical probe system S. Therefore, the actual test temperature environment applied to the test region T2 of the optical probe system S can be precisely controlled by the heating element 311 only or the cooperation of the heating element 311 and the cooling element 312.

### Seventh Embodiment

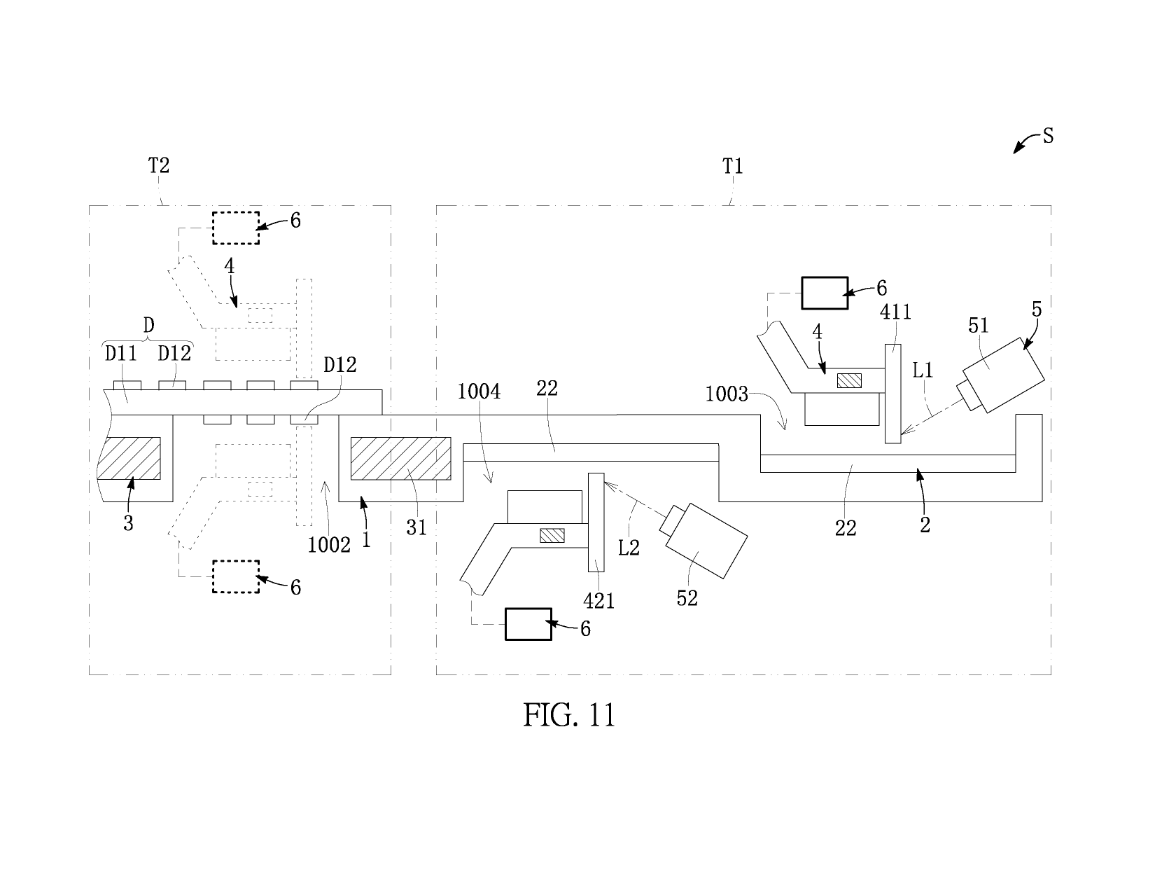

Referring to FIG. 11, a seventh embodiment of the present disclosure provides an optical probe system S, which may include a thermal main chuck 1, a calibration chuck 2, a thermal control module 3 and an optical probe assembly 4. Comparing FIG. 11 with FIG. 3 to FIG. 10, the main difference between the seventh embodiment and the first to sixth embodiments described above is as follows:

For example, as shown in FIG. 11, in one feasible embodiment, the thermal main chuck 1 may have a top concave groove 1003 for partially accommodating the at least one top optical probe 411 during the calibration of the at least one top optical probe 411 within the simulated test temperature environment applied to the calibration region T1 of the calibration chuck 2, thereby simulating a situation where the at least one top optical probe 411 is located above the thermal main chuck 1 configured as a grid chuck for optically or electrically test the at least one device under test D.

For example, as shown in FIG. 11, in one feasible embodiment, the thermal main chuck 1 may further have a bottom concave groove 1004 for partially accommodating the at least one bottom optical probe 421 during the calibration of the at least one bottom optical probe 421 within the simulated test temperature environment applied to the calibration region T1 of the calibration chuck 2, thereby simulating a situation where the at least one bottom optical probe 421 is located below the thermal main chuck 1 configured as a grid chuck for optically or electrically test the at least one device under test D.

It should be noted that, for example, when the thermal main chuck 1 and the calibration chuck 2 provided by the optical probe system S are separated (or thermally isolated) from each other, the top concave groove 1003 and the bottom concave groove 1004 can also be provided by the calibration chuck body 21 according to different embodiment.

It should be noted that, for example, the image capturing device 5 can be optionally (selectively) configured to observe the optical probe assembly 4 through a first side-viewing optical path L1 (such as a first oblique side-viewing optical path for the top image capturing unit 51), or a second side-viewing optical path L2 (such as a second oblique side-viewing optical path for the bottom image capturing unit 52).

### Eighth Embodiment

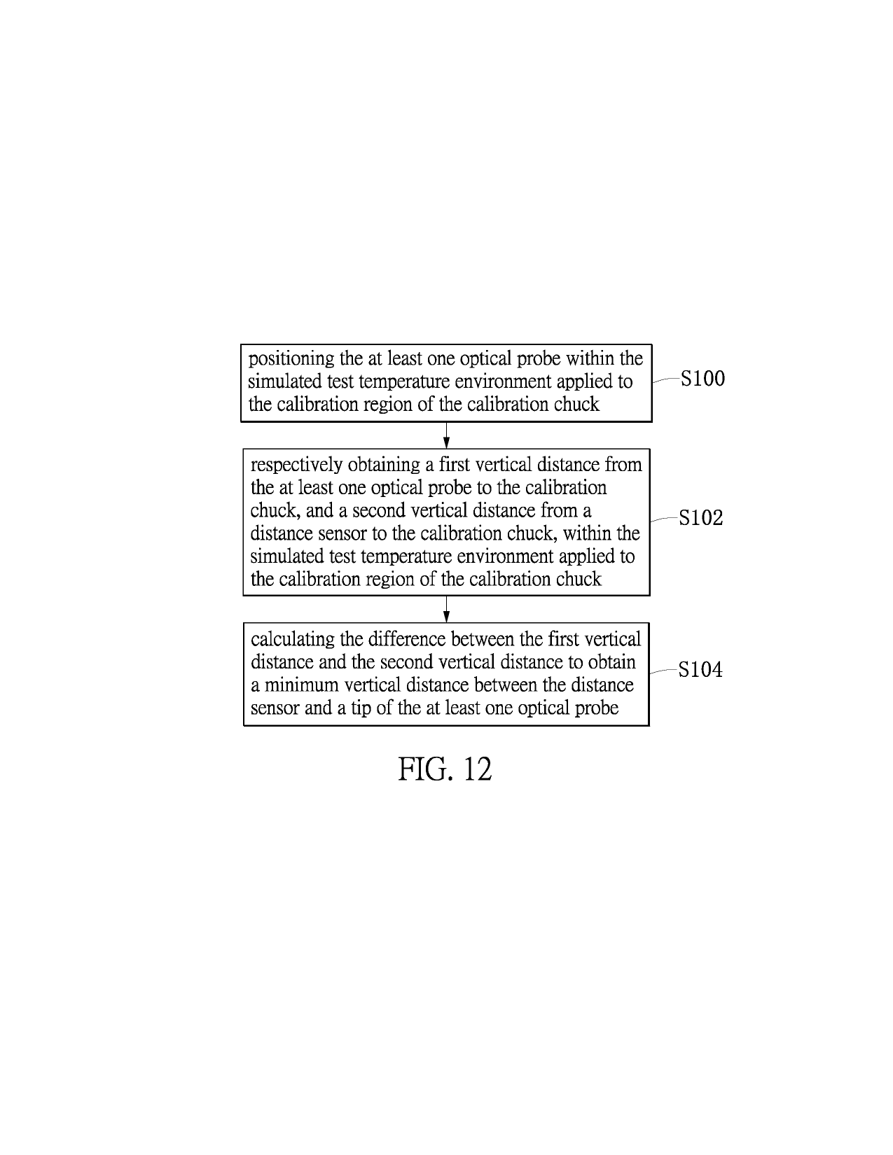

Referring to FIG. 12, an eighth embodiment of the present disclosure provides a distance measuring method for at least one optical probe (such as the at least one top optical probe 411 and/or the at least one bottom optical probe 421) provided by the optical probe system S as described in the first to seventh embodiments above (referring to FIG. 3 to FIG. 11), which may at least include the following processes: firstly, positioning the at least one optical probe (such as the at least one top optical probe 411 and/or the at least one bottom optical probe 421) within the simulated test temperature environment applied to the calibration region T1 of the calibration chuck 2 (step S100); next, respectively obtaining a first vertical distance H1 from the at least one optical probe (such as the tip of the at least one top optical probe 411 and/or the tip of the at least one bottom optical probe 421) to the calibration chuck 2 (such as a first calibration surface 2212 or a second calibration surface 2222 of the optical calibration structure 22), and a second vertical distance H2 from a distance sensor (such as a sensing area of the top distance sensor 412 and/or a sensing area of the bottom distance sensor 422) to the calibration chuck 2 (such as a first calibration surface 2212 or a second calibration surface 2222 of the optical calibration structure 22), within the simulated test temperature environment applied to the calibration region T1 of the calibration chuck 2 (step S102); and then calculating the difference between the first vertical distance H1 and the second vertical distance H2 to obtain a minimum vertical distance (i.e., a calibrated fiber-to-sensor distance d1) between the distance sensor (such as the sensing area of the top distance sensor 412 and/or the sensing area of the bottom distance sensor 422) and a tip of the at least one optical probe (such as the at least one top optical probe 411 and/or the at least one bottom optical probe 421) (step S104). Therefore, the calibrated fiber-to-sensor distance d1 measured at the simulated test temperature environment applied to the calibration region T1 of the calibration chuck 2 can be obtained accurately and quickly.

### Ninth Embodiment

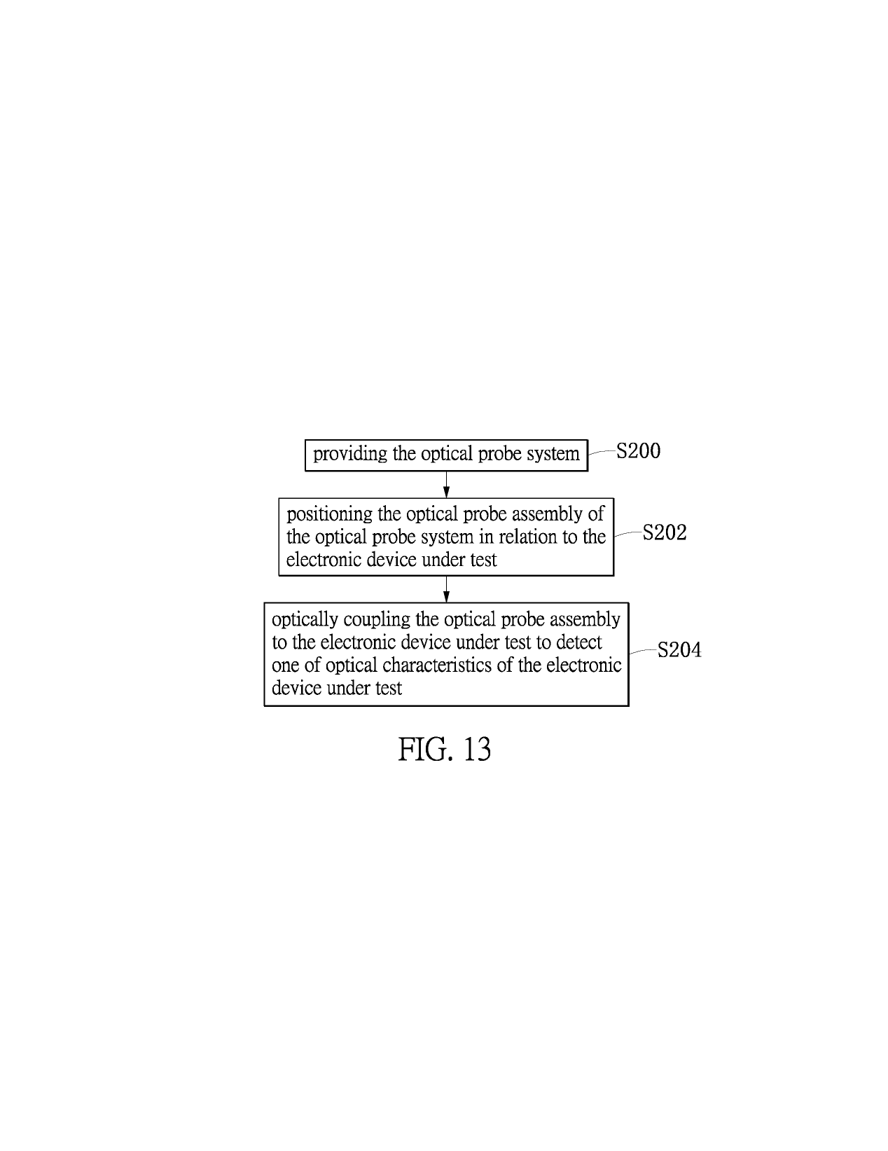

Referring to FIG. 13, a ninth embodiment of the present disclosure provides a method of performing an optical testing on an electronic device under test D, which may at least include: firstly, providing the optical probe system S as described in the first to seventh embodiments above (referring to FIG. 3 to FIG. 11) (step S200); next, positioning the optical probe assembly 4 of the optical probe system S in relation to the electronic device under test D (step S202); and then optically coupling the optical probe assembly 4 to the electronic device under test D to detect one of optical characteristics of the electronic device under test D (step S204).

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A calibration chuck for an optical probe system, comprising:
a calibration chuck body; and
an optical calibration structure carried by the calibration chuck body, wherein the optical calibration structure is optionally configured to provide a viewing optical path for observation of at least one optical probe of the optical probe system;
wherein a thermal control module is configured to be thermally coupled to the calibration chuck body, and the thermal control module is optionally configured to provide a simulated test temperature environment applied to a calibration region of the calibration chuck to match an actual test temperature environment applied to the optical probe system.

2. The calibration chuck according to claim 1, wherein the difference between two temperatures respectively obtained by the at least one optical probe provided by the optical probe system and the optical calibration structure respectively from the thermal control module is within a predetermined range.

3. The calibration chuck according to claim 1, wherein the optical calibration structure includes a light reflecting element disposed on a chuck surface of the calibration chuck body to provide a light reflecting surface, and the optical calibration structure is optionally configured to provide the viewing optical path through the light reflecting surface for an image capturing device provided by the optical probe system.

4. The calibration chuck according to claim 1, wherein the calibration chuck and a thermal main chuck provided by the optical probe system are separated from each other to respectively use two independent thermal control units of the thermal control module.

5. The calibration chuck according to claim 1, wherein the calibration chuck is carried by a thermal main chuck provided by the optical probe system, so that the thermal main chuck and the calibration chuck share the thermal control module.

6. The calibration chuck according to claim 1, wherein the optical calibration structure includes a top optical calibration unit disposed on a top side of the calibration chuck body and optionally configured to provide a top viewing optical path for a top image capturing device provided by the optical probe system.

7. The calibration chuck according to claim 1, wherein the optical calibration structure includes a bottom optical calibration structure disposed on a bottom side of the calibration chuck body and optionally configured to provide a bottom viewing optical path for a bottom image capturing device provided by the optical probe system.

8. The calibration chuck according to claim 1, wherein the thermal control module is optionally configured to regulate the simulated test temperature environment within a predefined temperature range to be substantially consistent with the actual test temperature environment.

9. The calibration chuck according to claim 1, wherein the thermal control module includes a heating element and a cooling element disposed in the calibration chuck body to be optionally configured to provide the simulated test temperature environment applied to the calibration chuck.

10. An optical probe system, comprising:
a thermal main chuck configured to carry at least one device under test (DUT);
a calibration chuck including a calibration chuck body and an optical calibration structure carried by the calibration chuck body;
a thermal control module thermally coupled to the thermal main chuck and the calibration chuck; and
an optical probe assembly configured to be movably disposed adjacent to one of the thermal main chuck and the calibration chuck;
wherein the optical probe assembly includes at least one optical probe configured to be movably disposed adjacent to one of the thermal main chuck and the calibration chuck, and a distance sensor disposed adjacent to the at least one optical probe;
wherein the thermal control module is optionally configured to provide a simulated test temperature environment applied to the calibration chuck, and an actual test temperature environment applied to the thermal main chuck.

11. The optical probe system according to claim 10,
wherein the thermal main chuck has a support surface configured to support the at least one DUT that includes a device substrate and a plurality of optical devices disposed on the device substrate;
wherein the thermal main chuck is configured as a grid chuck having at least one through opening;
wherein the thermal main chuck has a top concave groove for partially accommodating at least one top optical probe of the optical probe assembly during the calibration of the at least one top optical probe within the simulated test temperature environment applied to a calibration region of the calibration chuck, thereby simulating a situation where the at least one top optical probe is located above the thermal main chuck configured as the grid chuck for optically or electrically test the at least one device under test;
wherein the thermal main chuck has a bottom concave groove for partially accommodating at least one bottom optical probe of the optical probe assembly during the calibration of the at least one bottom optical probe within the simulated test temperature environment applied to the calibration region of the calibration chuck;
wherein the optical probe system further comprises a signal generation and analysis module optionally configured to provide an optical test signal to the optical probe assembly or receive an optical resultant signal from the optical probe assembly;
wherein the optical probe system further comprises an image capturing device configured to be movably disposed adjacent to the calibration chuck; and
wherein, when the optical probe assembly is configured to be movably disposed adjacent to the calibration chuck, the image capturing device is optionally configured to observe the optical probe assembly through a viewing optical path provided by the optical calibration structure.

12. The optical probe system according to claim 10, wherein the thermal control module includes a main thermal control unit thermally coupled to the thermal main chuck and an auxiliary thermal control unit thermally coupled to the calibration chuck, the thermal main chuck and the calibration chuck are separated from each other, and the main thermal control unit and the auxiliary thermal control unit are separated from each other.

13. The optical probe system according to claim 10, wherein the thermal control module includes a main thermal control unit thermally coupled to the thermal main chuck and the calibration chuck, the calibration chuck is carried by the thermal main chuck, and the thermal main chuck and the calibration chuck share the main thermal control unit of the thermal control module.

14. The optical probe system according to claim 10,
wherein the optical probe assembly includes at least one top optical probe configured to be movably disposed above one of the thermal main chuck and the calibration chuck, and a top distance sensor disposed adjacent to the at least one top optical probe;
wherein the optical calibration structure includes a top optical calibration unit disposed on a top side of the calibration chuck body;
wherein the optical probe system further comprises an image capturing device configured to be movably disposed adjacent to the calibration chuck;
wherein the image capturing device includes a top image capturing unit configured to be movably disposed above the calibration chuck to vertically correspond to the top optical calibration unit of the calibration chuck; and
wherein the top image capturing device is optionally configured to observe the at least one top optical probe through a top viewing optical path provided by the top optical calibration unit.

15. The optical probe system according to claim 10,
wherein the optical probe assembly includes at least one bottom optical probe configured to be movably disposed below one of the thermal main chuck and the calibration chuck, and a bottom distance sensor disposed adjacent to the at least one bottom optical probe;
wherein the optical calibration structure includes a bottom optical calibration unit disposed on a bottom side of the calibration chuck body;
wherein the optical probe system further comprises an image capturing device configured to be movably disposed adjacent to the calibration chuck;
wherein the image capturing device includes a bottom image capturing unit configured to be movably disposed below the calibration chuck to vertically correspond to the bottom optical calibration unit of the calibration chuck; and
wherein the bottom image capturing device is optionally configured to observe the at least one bottom optical probe through a bottom viewing optical path provided by the bottom optical calibration unit.

16. The optical probe system according to claim 10, wherein the temperature difference between the simulated test temperature environment applied to the calibration chuck and the actual test temperature environment applied to the thermal main chuck is within 5%.

17. The optical probe system according to claim 10, wherein the optical probe assembly includes an environment temperature sensor disposed thereon to real-time monitor the simulated test temperature environment and the actual test temperature environment, and the thermal control module is optionally configured to regulate the simulated test temperature environment and the actual test temperature environment according to a real-time temperature feedback signal provided from the environment temperature sensor.

18. A distance measuring method for at least one optical probe provided by the optical probe system as claimed in claim 10, comprising:
positioning the at least one optical probe within the simulated test temperature environment applied to the calibration chuck;
respectively obtaining a first vertical distance from the at least one optical probe to the calibration chuck and a second vertical distance from a distance sensor to the calibration chuck, within the simulated test temperature environment applied to the calibration chuck; and
calculating the difference between the first vertical distance and the second vertical distance to obtain a minimum vertical distance between the distance sensor and a tip of the at least one optical probe.

19. A method of performing an optical testing on an electronic device under test, comprising:
providing the optical probe system as claimed in claim 10;
positioning the optical probe assembly of the optical probe system in relation to the electronic device under test; and
optically coupling the optical probe assembly to the electronic device under test to detect one of optical characteristics of the electronic device under test.

20. An electronic device under test configured to be tested by the method as claimed in claim 19.
